(19) United States
(12) Patent Application Publication
(10) Pub. No.: US 2015/0020968 A1
(43) Pub. Date: Jan. 22, 2015

(54) SUBSTRATE PROCESSING APPARATUS AND SUBSTRATE PROCESSING METHOD

(71) Applicant: DAINIPPON SCREEN MFG. CO., LTD., Kyoto (JP)

(72) Inventor: Masahiro KIMURA, Kyoto (JP)

(73) Assignee: DAINIPPON SCREEN MFG. CO., LTD.

(21) Appl. No.: 14/505,092

(22) Filed: Oct. 2, 2014

Related U.S. Application Data
(63) Continuation of application No. 11/668,777, filed on Jan. 30, 2007.

(30) Foreign Application Priority Data
Jan. 30, 2006 (JP) 2006-020388
Jan. 30, 2006 (JP) 2006-020412

(51) Int. Cl. H01L 21/67

(52) U.S. Cl. CPC H01L 21/67086; H01L 21/67057
USPC 156/345.18

(57) ABSTRACT

A substrate processing apparatus of the present invention comprises a cooling mechanism for cooling a processing solution and a filter for removing impurities contained in the processing solution, at some midpoint in a circulation path of the processing solution. With this constitution, the substrate processing apparatus can precipitate the impurities dissolved in the processing solution and remove the precipitated impurities. It therefore becomes possible to maintain the performance of the processing solution and reuse the processing solution. Further, the frequency of changing the processing solution to a new solution decreases, and this causes an increase in availability of the substrate processing apparatus and a decrease in consumption and drainage of the processing solution.

### BACKGROUND OF THE INVENTION

1. Field of the Invention

The present invention relates to a substrate processing apparatus and a substrate processing method for performing predetermined processings, such as cleaning and etching, on substrates such as semiconductor wafers, glass substrates for liquid crystal displays and glass substrates for PDPs.

2. Description of the Background Art

In the background art, a substrate processing apparatus for processing substrates with a processing solution is well known in the manufacturing process for substrates. FIG. 11 is a view showing a general constitution of a substrate processing apparatus 200 of the background art. The substrate processing apparatus 200 of the background art comprises a processing bath 210 for pooling a processing solution therein and processes substrates W by immersing the substrates W in a processing solution pooled inside the processing bath 210. The substrate processing apparatus 200 further comprises a circulation part 220 for circulating the processing solution with the pressure of a circulation pump 221. The processing solution is filtered by a filter 222 provided at some midpoint in a circulation path. The processing solution is heated by a heater 211 provided in the processing bath 210 and a heater 223 provided at some midpoint in the circulation path and kept at a predetermined temperature suitable for the processing of the substrates W.

In the substrate processing apparatus 200 of the background art, however, the constitution of the ingredients of the processing solution sometimes changes, and this causes deterioration in performance of the processing solution as the processing for the substrates W proceeds. In a case where a surface of each substrate is etched by using a processing solution containing phosphoric acid, for example, an oxide or a nitride eluted from the surface of the substrate is sometimes mixed as an impurity into the processing solution, causing deterioration in performance of the processing solution for etching. Therefore, the substrate processing apparatus 200 of the background art needs frequent changes of the processing solution to a new solution and this results in a decrease in availability of the substrate processing apparatus 200 and an increase in consumption and drainage of the processing solution.

### SUMMARY OF THE INVENTION

The present invention is intended for a substrate processing apparatus for processing substrates with a processing solution.

According to the present invention, the substrate processing apparatus comprises a processing bath for accommodating a substrate and pooling a processing solution therein, a circulation path for supplying a processing solution discharged from the processing bath to the processing bath again, cooling part for cooling a processing solution at some midpoint in the circulation path, and impurity removing part for removing impurities contained in a processing solution on the downstream side of the cooling part at some midpoint in the circulation path.

The substrate processing apparatus can thereby precipitate the impurities dissolved in the processing solution and remove the precipitated impurities. It therefore becomes possible to maintain the performance of the processing solution and reuse the processing solution. Further, since the frequency of changing the processing solution to a new solution decreases, this causes an increase in availability of the substrate processing apparatus and a decrease in consumption and drainage of the processing solution.

Preferably, the substrate processing apparatus further comprises heating part for heating a processing solution on the downstream side of the impurity removing part at some midpoint in the circulation path.

It is therefore possible to remove the impurities in the processing solution while keeping the temperature of the processing solution in the processing bath.

Preferably, the processing bath comprises an inside bath for accommodating a substrate and processing the substrate and an outside bath provided at an upper portion outside the inside bath, for receiving a processing solution which overflows from the inside bath, and the circulation path supplies a processing solution discharged from the outside bath to the inside bath again.

It is therefore possible to remove the impurities in the processing solution in the circulation path while processing the substrate with the processing solution overflowing in the processing bath. This further increases the availability of the substrate processing apparatus.

Preferably, the circulation path supplies a processing solution discharged from a bottom of the processing bath to the processing bath again.

It is therefore possible to quickly collect the processing solution and remove the impurities in the processing solution. This further increases the availability of the substrate processing apparatus.

Preferably, the circulation path comprises a first circulation path and a second circulation path, and the impurity removing part is provided in each of the first circulation path and the second circulation path, and the substrate processing apparatus further comprises circulation path switching part for switching between the first circulation path and the second circulation path.

If impurities are accumulated in one of the impurity removing part, the other impurity removing part can be used by switching of the circulation paths. This further increases the availability of the substrate processing apparatus.

Preferably, the impurity removing part comprises a filter for filtering out impurities in a processing solution, and the substrate processing apparatus further comprises filter cleaning part for cleaning the filter.

It is thereby possible to resolve clogging of the filter even without changing the filter.

Preferably, the filter cleaning part comprises filter cleaning solution supply part for supplying a filter cleaning solution which dissolves impurities to the filter.

It is thereby possible to dissolve the impurities accumulated in the filter and effectively resolve clogging of the filter.

Preferably, the substrate processing apparatus further comprises a drainage path which branches out from the circulation path on the downstream side of the filter at some midpoint in the circulation path, and drainage switching part for switching between the circulation path and the drainage path.

For cleaning the filter, a passage for the solution is switched to the drainage path and it is thereby possible to prevent the filter cleaning solution from being supplied to the processing bath.

Preferably, the substrate processing apparatus further comprises processing solution supply part for supplying a processing solution on the upstream side of the filter at some midpoint in the circulation path.

It is thereby possible to prevent the filter cleaning solution from being adhered to the filter and left thereon.

Preferably, the substrate processing apparatus further comprises a processing solution pooling bath for pooling a processing solution therein on the downstream side of the impurity removing part at some midpoint in the circulation path, and in the substrate processing apparatus, the heating part heats the processing solution pooled in the processing solution pooling bath.

It is therefore possible to sufficiently heat the processing solution.

According to another aspect of the present invention, the substrate processing apparatus comprises a processing bath for accommodating a substrate and pooling a processing solution therein, a circulation path for supplying a processing solution discharged from the processing bath to the processing bath again, a cooling bath for pooling a processing solution and cooling the processing solution at some midpoint in the circulation path, and discharge part for discharging impurities settled in the cooling bath from the cooling bath.

The substrate processing apparatus can thereby precipitate the impurities dissolved in the processing solution, to be settled on the bottom of the cooling bath, and remove the settled impurities. It therefore becomes possible to maintain the performance of the processing solution and reuse the processing solution. Further, the frequency of changing the processing solution to a new solution decreases, and this causes an increase in availability of the substrate processing apparatus and a decrease in consumption and drainage of the processing solution.

Preferably, the substrate processing apparatus further comprises a circulation mechanism for drawing a supernatant fluid of a processing solution pooled in the cooling bath and supplying the processing solution toward the downstream of a circulation path.

It is thereby possible to carry only the processing solution to the circulation path with the settled impurities left in the cooling bath.

Preferably, the substrate processing apparatus further comprises heating part for heating a processing solution on the downstream side of the cooling bath at some midpoint in the circulation path.

It is thereby possible to remove the impurities in the processing solution while keeping the temperature of the processing solution in the processing bath.

Preferably, the processing bath comprises an inside bath for accommodating a substrate and processing the substrate and an outside bath provided at an upper portion outside the inside bath, for receiving a processing solution which overflows from the inside bath, and the circulation path supplies a processing solution discharged from the outside bath to the inside bath again.

It is therefore possible to remove the impurities in the processing solution in the circulation path while processing the substrate with the processing solution overflowing in the processing bath. This further increases the availability of the substrate processing apparatus.

Preferably, the circulation path supplies a processing solution discharged from a bottom of the processing bath to the processing bath again.

It is therefore possible to quickly collect the processing solution and remove the impurities in the processing solution. This further increases the availability of the substrate processing apparatus.

Preferably, the circulation path comprises a first circulation path and a second circulation path, and the cooling bath is provided in each of the first circulation path and the second circulation path, and the substrate processing apparatus further comprises circulation path switching part for switching between the first circulation path and the second circulation path.

If impurities are accumulated in one of the cooling bath, the other cooling bath can be used by switching of the circulation paths. This further increases the availability of the substrate processing apparatus.

Preferably, the substrate processing apparatus further comprises a filter for filtering out impurities in a processing solution on the downstream side of the cooling bath in the circulation path.

If a very small amount of impurities are carried to the following circulation path, it is thereby possible to filter out and remove the impurities.

Preferably, the substrate processing apparatus further comprises processing solution supply part for supplying a processing solution on the upstream side of the cooling bath at some midpoint in the circulation path.

For discharging the impurities from the cooling bath, it is possible to wash out the impurities remaining in the cooling bath with the processing solution.

Preferably, the substrate processing apparatus further comprises a processing solution pooling bath for pooling a processing solution therein on the downstream side of the cooling bath at some midpoint in the circulation path, and in the substrate processing apparatus, the heating part heats the processing solution pooled in the processing solution pooling bath.

It is therefore possible to sufficiently heat the processing solution.

The present invention is also intended for a substrate processing method for processing substrates with a processing solution.

It is an object of the present invention to provide a technique to maintain the performance of the processing solution which is used for processing substrates in a substrate processing apparatus, increase the availability of the substrate processing apparatus and decrease the consumption and drainage of the processing solution.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a constitution of a substrate processing apparatus in accordance with a first preferred embodiment;

FIG. 2 is a block diagram showing an electric connection between a control part and constituent elements in accordance with the first preferred embodiment;

FIG. 3 is a flowchart showing an operation flow of the substrate processing apparatus in accordance with the first preferred embodiment;

FIG. 4 is a flowchart showing a detailed operation flow for cleaning a filter in accordance with the first preferred embodiment;

FIG. 5 is a flowchart showing an operation flow of the substrate processing apparatus in accordance with the first preferred embodiment;

FIG. 6 is a view showing a constitution of a substrate processing apparatus in accordance with a second preferred embodiment;

FIG. 7 is a block diagram showing an electric connection between the control part and the constituent elements in accordance with the second preferred embodiment;

FIG. 8 is a flowchart showing an operation flow of the substrate processing apparatus in accordance with the second preferred embodiment;

FIG. 9 is a flowchart showing a detailed operation flow for discharging impurities in accordance with the second preferred embodiment;

FIG. 10 is a flowchart showing an operation flow of the substrate processing apparatus in accordance with the second preferred embodiment; and

FIG. 11 is a view showing a general constitution of a substrate processing apparatus of the background art.

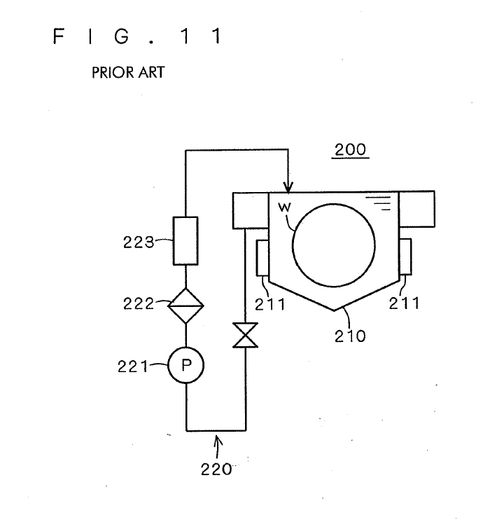

### DESCRIPTION OF THE PREFERRED EMBODIMENTS

Hereinafter, discussion will be made on preferred embodiments of the present invention, with reference to the drawings.

### 1. The First Preferred Embodiment

<1-1. Constitution of Substrate Processing Apparatus>

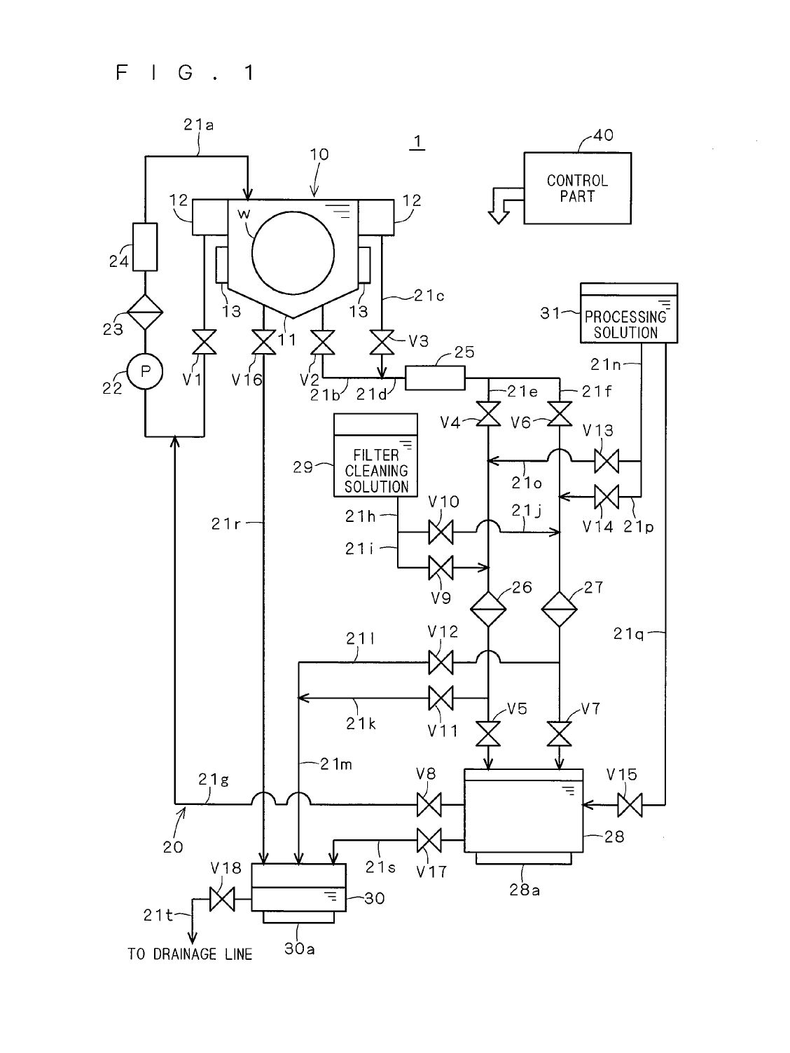

FIG. 1 is a view showing a constitution of a substrate processing apparatus 1 in accordance with one preferred embodiment of the present invention. This substrate processing apparatus 1 is an apparatus for processing a plurality of substrates W, by immersing the substrates W in a processing solution pooled in a processing bath 10. The substrate processing apparatus 1 mainly comprises the processing bath 10, a piping part 20 and a control part 40. In the first preferred embodiment, discussion will be made on a case where a phosphoric acid (H₃PO₄) solution is used as the processing solution and etching is performed on a surface of each substrate W.

The processing bath 10 is a container for pooling the processing solution therein. The processing bath 10 comprises an inside bath 11 for immersing the substrates W therein and outside baths 12 provided on the upper ends of the outside surface of the inside bath 11. The processing solution supplied to the inside bath 11 is pooled in the inside bath 11 and then overflows into the outside bath 12 from an opening at the upper portion of the inside bath 11. On both sides of the inside bath 11, heaters 13 are provided. When the heaters 13 are operated, the processing solution pooled inside the inside bath 11 is heated and kept at a predetermined temperature (e.g., 160° C.).

At the upper portion of the processing bath 10 provided is a not-shown lifter for holding the substrates W. The substrates W are held by the lifter and conveyed vertically, moving between a drawing-up position at an upside of the processing bath 10 and an immersing position inside the inside bath 11 (the position shown in FIG. 1). When the processing solution is pooled in the inside bath 11 and the substrates W are lowered, the substrates W are immersed into the processing solution and the surfaces of the substrates W are etched.

The piping part 20 consists of a plurality of pipes 21a to 21t. The pipe 21a has an upstream end which is connected to the outside bath 12 and a downstream end which is connected to the inside bath 11. In the path of the pipe 21a, a valve V1, a circulation pump 22, a filter 23 and a heater 24 are provided in this order from the upstream side. Therefore, when the valve V1 is opened and the circulation pump 22 is operated, the processing solution which overflows into the outside bath 12 from the inside bath 11 flows into the pipe 21a, circulating therein toward the inside bath 11. On the way in the path of the pipe 21a to the inside bath 11, impurities in the processing solution are removed by the filter 23. When the heater 24 is operated, the circulating processing solution is heated and kept at a predetermined temperature.

The pipe 21b has an upstream end which is connected to the bottom of the inside bath 11 and at some midpoint in the path of the pipe 21b, a valve V2 is connected thereto. Therefore, when the valve V2 is opened, the processing solution pooled in the inside bath 11 quickly flows out into the pipe 21b. The pipe 21c has an upstream end which is connected to the outside bath 12 and at some midpoint in the path of the pipe 21c, a valve V3 is inserted. Therefore, when the valve V3 is opened, the processing solution which overflows into the outside bath 12 flows out into the pipe 21c.

The downstream end of the pipe 21b and that of the pipe 21c are joined into the pipe 21d. At some midpoint in the path of the pipe 21d provided is a cooling mechanism 25 for cooling the processing solution. Therefore, when the cooling mechanism 25 is operated, the processing solution flowing in the pipe 21d is cooled.

The downstream end of the pipe 21d branches out into two pipes 21e and 21f. At some midpoint in the path of the pipe 21e, a valve V4, a filter 26 and a valve V5 are provided in this order from the upstream side. Therefore, when the valves V4 and V5 are opened, the processing solution flows in the pipe 21e and the impurities contained in the processing solution is filtered by the filter 26. Similarly, at some midpoint in the path of the pipe 21f, a valve V6, a filter 27 and a valve V7 are provided in this order from the upstream side. Therefore, when the valves V6 and V7 are opened, the processing solution flows in the pipe 21f and the impurities contained in the processing solution is filtered by the filter 27.

The downstream ends of the pipes 21e and 21f are connected to one reserve temperature-controlled tank 28. The processing solution carried in the pipes 21e and 21f flows into the reserve temperature-controlled tank 28 and is temporarily pooled in the reserve temperature-controlled tank 28. A heater 28a is provided on the bottom side of the reserve temperature-controlled tank 28. Therefore, when the heater 28a is operated, the processing solution pooled in the reserve temperature-controlled tank 28 is heated up to a predetermined temperature.

The pipe 21g has an upstream end which is connected to the reserve temperature-controlled tank 28 and a downstream end which is connected to the upstream side of the circulation pump 22 in the pipe 21a. At some midpoint in the path of the pipe 21g, a valve V8 is inserted. Therefore, when the valve V8 is opened, the processing solution pooled in the reserve temperature-controlled tank 28 flows into the pipe 21a through the pipe 21g and supplied to the inside bath 11 via the circulation pump 22, the filter 23 and the heater 24.

The filter cleaning solution supplier 29 is a fluid supply for supplying a filter cleaning solution to clean the filters 26 and 27. The filter cleaning solution cleans the filters 26 and 27 by dissolving the impurities filtered out by the filters 26 and 27. As the filter cleaning solution, for example, used is dilute hydrofluoric acid which dissolves etching residues such as SiO₂ or SiN₃ at a low temperature.

To the filter cleaning solution supplier 29, the pipe 21h is connected and the downstream end of the pipe 21h branches out into the pipes 21i and 21j. At some midpoint in the path of the pipe 21i, a valve V9 is inserted, and the downstream end of the pipe 21i is connected to the upstream side of the filter 26 in the pipe 21e. Therefore, when the valve V9 is opened, the filter cleaning solution is supplied from the filter cleaning solution supplier 29 to the filter 26 through the pipes 21h, 21i and 21e. Similarly, at some midpoint in the path of the pipe 21j, a valve V10 is inserted, and the downstream end of the pipe 21j is connected to the upstream side of the filter 27 in the pipe 21f. Therefore, when the valve V10 is opened, the filter cleaning solution is supplied from the filter cleaning solution supplier 29 to the filter 27 through the pipes 21h, 21j and 21f.

Between the filter 26 and the valve V5 in the pipe 21e, the pipe 21k is connected, and at some midpoint in the path of the pipe 21k, a valve V11 is inserted. Further, between the filter 27 and the valve V7 in the pipe 21f, the pipe 21l is connected, and at some midpoint in the path of the pipe 21l, a valve V12 is inserted. The downstream end of the pipe 21k and that of the pipe 21l are joined into the pipe 21m, and the downstream end of the pipe 21m is connected to a drainage cooling tank 30. Therefore, when the valve V5 is closed and the valve V11 is opened, the processing solution or the filter cleaning solution passing through the filter 26 is discharged to the drainage cooling tank 30 through the pipes 21e, 21k and 21m. Further, when the valve V7 is closed and the valve V12 is opened, the processing solution or the filter cleaning solution passing through the filter 27 is discharged to the drainage cooling tank 30 through the pipes 21f, 21l and 21m.

A processing solution supplier 31 is a fluid supply for supplying a new (unused) processing solution. To the processing solution supplier 31, the pipe 21n is connected. The downstream end of the pipe 21n branches out into the pipes 21o and 21p. At some midpoint in the path of the pipe 21o, a valve V13 is inserted, and the downstream end of the pipe 21o is connected to the upstream side of the filter 26 in the pipe 21e. Therefore, when the valve V13 is opened, the processing solution is supplied from the processing solution supplier 31 to the filter 26 through the pipes 21n, 21o and 21 e. Similarly, at some midpoint in the path of the pipe 21p, a valve V14 is inserted, and the downstream end of the pipe 21p is connected to the upstream side of the filter 27 in the pipe 21f. Therefore, when the valve V14 is opened, the processing solution is supplied from the processing solution supplier 31 to the filter 27 through the pipes 21n, 21p and 21f.

To the processing solution supplier 31, the pipe 21q is also connected. At some midpoint in the path of the pipe 21q, a valve V15 is inserted, and the downstream end of the pipe 21q is connected to the reserve temperature-controlled tank 28. Therefore, when the valve V15 is opened, a new processing solution is supplied from the processing solution supplier 31 to the reserve temperature-controlled tank 28.

The pipe 21r has an upstream end which is connected to the bottom of the inside bath 11 and a downstream end which is connected to the drainage cooling tank 30. At some midpoint in the path of the pipe 21r, a valve V16 is inserted. Therefore, when the valve V16 is opened, the processing solution pooled in the inside bath 11 is quickly discharged into the drainage cooling tank 30 through the pipe 21r.

The pipe 21s has an upstream end which is connected to the reserve temperature-controlled tank 28 and a downstream end which is connected to the drainage cooling tank 30. At some midpoint in the path of the pipe 21s, a valve V17 is inserted. Therefore, when the valve V17 is opened, the processing solution pooled in the reserve temperature-controlled tank 28 is discharged into the drainage cooling tank 30 through the pipe 21s.

A cooling mechanism 30a is provided on the bottom side of the drainage cooling tank 30. When the cooling mechanism 30a is operated, the processing solution or the filter cleaning solution pooled in the drainage cooling tank 30 is cooled up to a temperature where it can be disposed of. Further, to the drainage cooling tank 30, the pipe 21t is connected. At some midpoint in the path of the pipe 21t, a valve V18 is inserted. The downstream end of the pipe 21t is connected to a drainage line. Therefore, when the valve V18 is opened, the processing solution or the filter cleaning solution cooled in the drainage cooling tank 30 is discharged into the drainage line.

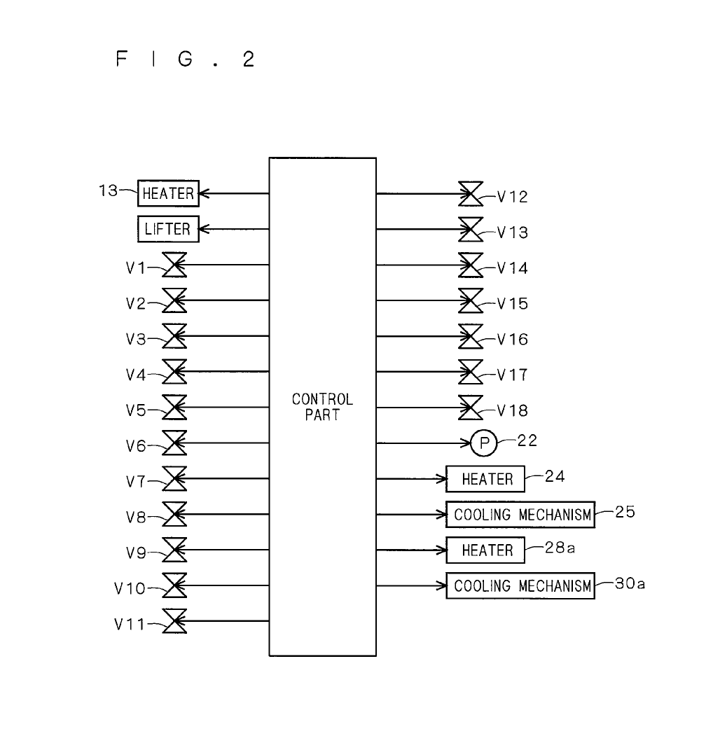

The control part 40 is an information processing part for controlling operations of constituent elements in the substrate processing apparatus 1. The control part 40 is formed of a computer consisting of a CPU and memories. FIG. 2 is a block diagram showing an electric connection between the control part 40 and the constituent elements. As shown in FIG. 2, the control part 40 is electrically connected to the heater 13, the lifter, the valves V1 to V18, the circulation pump 22, the heater 24, the cooling mechanism 25, the heater 28a and the cooling mechanism 30a, and controls the operations of those constituents.

<1-2. Operation of Substrate Processing Apparatus (For Continuously Removing Impurities>

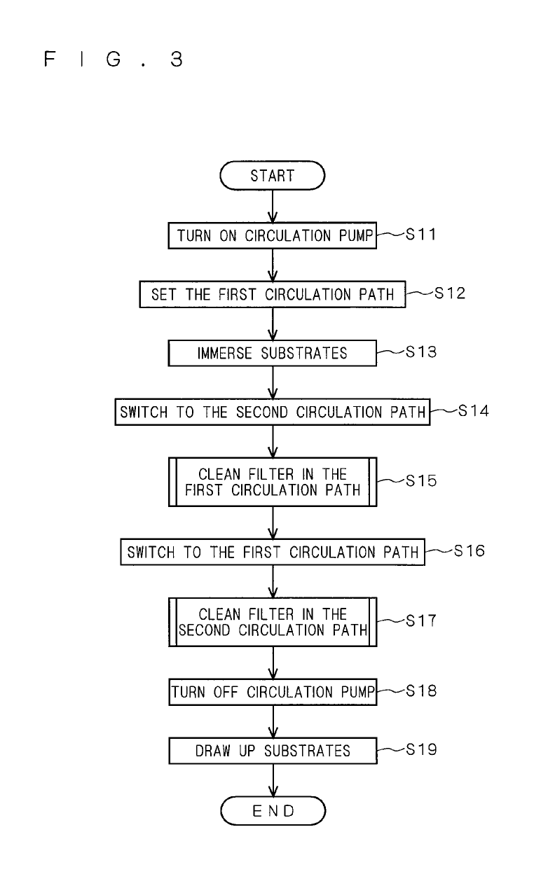

Next, discussion will be made on an operation of the substrate processing apparatus 1 having the above constitution. The discussion will start with a case where the substrates W are processed in the processing bath 10 while impurities in the processing solution are continuously removed, with reference to the flowchart of FIG. 3. To perform the operation of the substrate processing apparatus 1 discussed below, the control part 40 controls the operations of the heater 13, the lifter, the valves V1 to V18, the circulation pump 22, the heater 24, the cooling mechanism 25, the heater 28a, the cooling mechanism 30a and the like.

First, in the substrate processing apparatus 1, the valves V8 and V15 are opened and the circulation pump 22 is operated (Step S11). The processing solution is thereby supplied from the processing solution supplier 31 to the inside bath 11 through the pipe 21q, the reserve temperature-controlled tank 28, the pipes 21g and 21a and pooled in the inside bath 11. When pooled up to the uppermost position of the inside bath 11, the processing solution overflows from the upper portion of the inside bath 11 into the outside bath 12.

When the processing solution is pooled in the inside bath 11, the heater 28a of the reserve temperature-controlled tank 28, the heater 24 in the pipe 21a and the heaters 13 of the inside bath 11 are operated. The processing solution pooled in the inside bath 11 is thereby heated and kept at a predetermined temperature (e.g., 160° C.) which is suitable for the etching operation.

Next, the valves V1, V2, V6, V7 and V9 to V18 are closed and the valves V3 to V5 and V8 are opened. A circulation path via the filter 26 (hereinafter, referred to as “the first circulation path”) is thereby set to serve as the passage for the processing solution (Step S12). In the first circulation path, the processing solution which overflows from the inside bath 11 into the outside bath 12 circulates through the pipes 21c, 21d and 21e, the reserve temperature-controlled tank 28 and the pipes 21g and 21a to the inside bath 11.

Subsequently, by lowering the lifter which holds the substrates W, the substrates W are immersed into the processing solution pooled in the inside bath 11 (Step S13). The oxide film or nitride film formed on the substrates W is thereby etched. The ingredients (SiO₂, SiN₃ or the like) of the oxide or nitride eluted from the surfaces of the substrates W by etching are mixed into the processing solution as impurities.

The processing solution containing the impurities overflows from the upper portion of the inside bath 11 into the outside bath 12 and begins to flow into the first circulation path from the outside bath 12. Then, the processing solution is cooled by the cooling mechanism 25 in the pipe 21d. Since the saturated dissolution concentration of the impurities to the processing solution decreases as the temperature of the processing solution falls, when the processing solution is cooled, the impurities dissolved in the processing solution are precipitated as solids. After that, by the filter 26 in the pipe 21e, the impurities in the processing solution are filtered out and only the processing solution is collected into the reserve temperature-controlled tank 28.

The reserve temperature-controlled tank 28 uses the heater 28a to heat the collected processing solution to a predetermined temperature again. Then, the processing solution heated in the reserve temperature-controlled tank 28 is supplied to the inside bath 11 through the pipes 21g and 21a and reused to process the substrates W. Further, the processing solution is heated by the heater 24 in the pipe 21a and the heaters 13 of the inside bath 11. It is thereby possible to prevent a decrease in temperature of the processing solution in the pipes 21g and 21a and keep the processing solution at the predetermined temperature.

After the substrates W have been immersed for a predetermined time, next, the valve V4 is closed and the valves V6 and V7 are opened. The passage for the processing solution is switched to the circulation path via the filter 27 (hereinafter, referred to as “the second circulation path”) (Step S14). In the second circulation path, the processing solution which overflows into the outside bath 12 circulates through the pipes 21c, 21d and 21f, the reserve temperature-controlled tank 28 and the pipes 21g and 21a to the inside bath 11.

In the second circulation path, like in the first circulation path, first, the processing solution is cooled by the cooling mechanism 25 in the pipe 21d. The impurities are precipitated as solids in the cooled processing solution, and the precipitated impurities are filtered out by the filter 27 in the pipe 21f. The processing solution collected into the reserve temperature-controlled tank 28 is heated by the heater 28a and supplied to the inside bath 11 through the pipes 21g and 21a. Thus, also in the second circulation path, the same cooling, filtering and heating as those in the first circulation path are performed while the processing solution circulates.

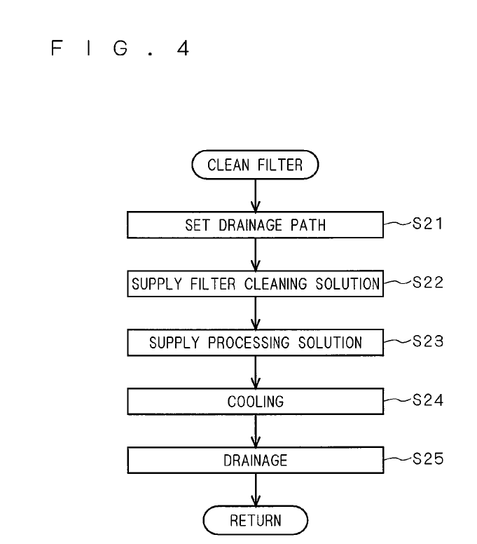

While the second circulation path is used, the filter 26 is cleaned in the first circulation path (Step S15). FIG. 4 is a flowchart showing a detailed operation flow for cleaning the filter 26. To clean the filter 26, first, the valve V5 is closed and the valve V11 is opened, and a path toward the drainage cooling tank 30 (drainage path) is set to serve as the passage for the solution (Step S21). Then, the valve V9 is opened, and the filter cleaning solution is supplied from the filter cleaning solution supplier 29 to the filter 26 through the pipes 21h, 21i and 21e (Step S22). The impurities accumulated in the filter 26 are dissolved again by the filter cleaning solution and can pass the filter 26. Then, the filter cleaning solution containing the ingredients of the impurities, after passing through the filter 26, is discharged to the drainage cooling tank 30 through the pipes 21e, 21k and 21m.

After that, the valve V9 is closed and the valve V13 is opened. A new processing solution is thereby supplied from the processing solution supplier 31 to the pipe 21e through the pipes 21n and 21o (Step S23). The processing solution supplied to the pipe 21e cleans off the filter cleaning solution adhered on the pipe 21e and the filter 26 and is discharged to the drainage cooling tank 30 through the pipes 21k and 21m. In the drainage cooling tank 30, the processing solution and the filter cleaning solution are cooled by the cooling mechanism 30a (Step S24). Then, after the processing solution and the filter cleaning solution are cooled up to the temperature where the solutions can be discharged, the valve V18 is opened and the processing solution and the filter cleaning solution are discharged to the drainage line (Step S25).

Referring back to FIG. 3, after a predetermined time from the time when the passage is switched to the second circulation path, next, the valve V6 is closed and the valves V4 and V5 are opened. The passage for the processing solution is switched to the first circulation path again (Step S16). In the first circulation path, like in the above-discussed Step S13, first, the processing solution is cooled by the cooling mechanism 25 in the pipe 21d. The impurities are precipitated as solids in the cooled processing solution, and the precipitated impurities are filtered out by the filter 26 in the pipe 21e. The processing solution collected into the reserve temperature-controlled tank 28 is heated by the heater 28a and supplied to the inside bath 11 through the pipes 21g and 21a.

While the first circulation path is used, the filter 27 is cleaned in the second circulation path (Step S17). The operation flow for cleaning the filter 27 is the same as that for cleaning the filter 26 as shown in FIG. 4. Specifically, first, the valve V7 is closed and the valve V12 is opened, and the path toward the drainage cooling tank 30 (drainage path) is set to serve as the passage for the solution (Step S21). Then, the valve V10 is opened and the filter cleaning solution is supplied from the filter cleaning solution supplier 29 to the filter 27 through the pipes 21h, 21j and 21 f (Step S22). The impurities accumulated in the filter 27 are dissolved again by the filter cleaning solution and can pass the filter 27. Then, the filter cleaning solution containing the ingredients of the impurities, after passing through the filter 27, is discharged to the drainage cooling tank 30 through the pipes 21f, 21l and 21m.

After that, the valve V10 is closed and the valve V14 is opened. A new processing solution is thereby supplied from the processing solution supplier 31 to the pipe 21f through the pipes 21n and 21p (Step S23). The processing solution supplied to the pipe 21f cleans off the filter cleaning solution adhered on the pipe 21f and the filter 27 and is discharged to the drainage cooling tank 30 through the pipes 21l and 21m. In the drainage cooling tank 30, the processing solution and the filter cleaning solution are cooled by the cooling mechanism 30a (Step S24). Then, after the processing solution and the filter cleaning solution are cooled up to the temperature where the solutions can be discharged, the valve V18 is opened and the processing solution and the filter cleaning solution are discharged to the drainage line (Step S25).

Referring back to FIG. 3, when the processing for the substrates W which takes a predetermined time is completed, the circulation pump 22 is stopped (Step S18). The circulation of the processing solution, using the first circulation path, is thereby stopped. Then, by raising the lifter, the substrates W are drawn up from the inside bath 11 (Step S19). Thus, the processing for the substrates W in the substrate processing apparatus 1 is completed.

As discussed above, the substrate processing apparatus 1 precipitates the impurities by cooling the processing solution and removes the precipitated impurities by using the filters 26 and 27. It therefore becomes possible to maintain the performance of the processing solution and reuse the processing solution. Further, the frequency of changing the processing solution to a new solution decreases, and this causes an increase in availability of the substrate processing apparatus 1 and a decrease in consumption and drainage of the processing solution.

Especially, the substrate processing apparatus 1 processes the substrates W while circulating the processing solution, and performs cooling, filtering and heating of the processing solution in the circulation path. For this reason, the substrate processing apparatus 1 can remove the impurities in the processing solution without stopping the processing for the substrates W in the processing bath 10. This further increases the availability of the substrate processing apparatus 1.

Further, the substrate processing apparatus 1 comprises the reserve temperature-controlled tank 28 for heating the processing solution on the downstream side of the filters 26 and 27 in the circulation path of the processing solution. The substrate processing apparatus 1 can therefore remove the impurities in the processing solution while keeping the temperature of the processing solution in the processing bath 10.

The substrate processing apparatus 1 further has the first and second circulation paths which are provided in parallel and can perform cooling, filtering and heating of the processing solution in an equal manner. By controlling opening and closing of the valves V4 to V7, switching between the first and second circulation paths can be performed. Therefore, if impurities are accumulated in one of the filters, the other filter can be used by switching of the circulation paths. This further increases the availability of the substrate processing apparatus 1.

Furthermore, the substrate processing apparatus 1 can use one circulation path while cleaning the filter in the other circulation path. It is therefore possible to resolve clogging of the filters 26 and 27 while continuously switching the circulation paths to be used. This further increases the availability of the substrate processing apparatus 1. The number of switching of the circulation paths is not limited to the above exemplary case but may be set as appropriate in accordance with the time period for the processing of the substrates W.

The substrate processing apparatus 1 further has drainage paths which branch out from the first and second circulation paths, respectively. By controlling opening and closing of the valves V5, V7, V11 and V12, switching between the main path and the drainage path in each circulation path can be performed. Therefore, for cleaning the filters 26 and 27, the passage for the solution can be switched to the drainage path and it is thereby possible to prevent the filter cleaning solution to be supplied to the processing bath 10.

Further, after supplying the filter cleaning solution to the filters 26 and 27, the substrate processing apparatus 1 supplies the processing solution to the pipes 21e and 21f and the filters 26 and 27. It is therefore possible to prevent the filter cleaning solution to be adhered to the pipes 21e and 21f or the filters 26 and 27 and left thereon.

<1-3. Operation of Substrate Processing Apparatus (For Removing Impurities at a Time>

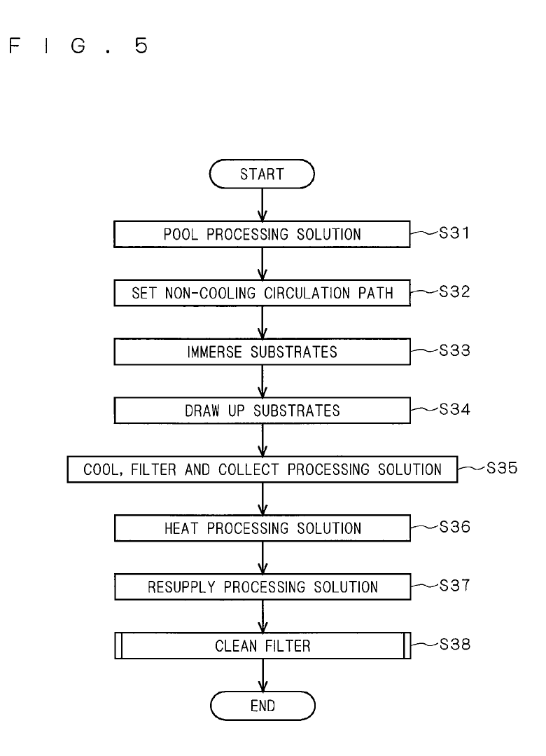

Next, discussion will be made on a case where after processing the substrates W, the above-discussed substrate processing apparatus 1 removes impurities in the processing solution at a time, with reference to the flowchart of FIG. 5. Also to perform the operation of the substrate processing apparatus 1 discussed below, the control part 40 controls the operations of the heater 13, the lifter, the valves V1 to V18, the circulation pump 22, the heater 24, the cooling mechanism 25, the heater 28a, the cooling mechanism 30a and the like.

First, in the substrate processing apparatus 1, the valves V8 and V15 are opened and the circulation pump 22 is operated. The processing solution is thereby supplied from the processing solution supplier 31 to the inside bath 11 through the pipe 21q, the reserve temperature-controlled tank 28, the pipes 21g and 21a and pooled in the inside bath 11 (Step S31). When pooled up to the uppermost position of the inside bath 11, the processing solution overflows from the upper portion of the inside bath 11 into the outside bath 12.

When the processing solution is pooled in the inside bath 11, the heater 28a of the reserve temperature-controlled tank 28, the heater 24 in the pipe 21a and the heaters 13 of the inside bath 11 are operated. The processing solution pooled in the inside bath 11 is thereby heated and kept at a predetermined temperature (e.g., 160° C.) which is suitable for the etching operation.

Next, the valves V2 to V18 are closed and the valve V1 is opened. A circulation path consisting only of the pipe 21a (hereinafter, referred to as “a non-cooling circulation path”) is thereby set to serve as the passage for the processing solution (Step S32). In the non-cooling circulation path, the processing solution which overflows from the inside bath 11 into the outside bath 12 circulates through the filter 23 and the heater 24 to the inside bath 11.

Subsequently, by lowering the lifter which holds the substrates W, the substrates W are immersed into the processing solution pooled in the inside bath 11 (Step S33). The oxide film or nitride film formed on the surfaces of the substrates W is thereby etched. The ingredients (SiO₂, SiN₃ or the like) of the oxide film or nitride film eluted from the surfaces of the substrates W by etching are mixed into the processing solution as impurities. Then, when the processing for the substrates W which takes a predetermined time is completed, the substrates W are drawn up from the inside bath 11 by raising the lifter (Step S34).

After drawing up the substrates W, the substrate processing apparatus 1 closes the valve V1 and opens the valves V2 to V5. The substrate processing apparatus 1 thereby collects the processing solution which is pooled in the inside bath 11 and the outside bath 12, in the reserve temperature-controlled tank 28 through the pipes 21b, 21c, 21d and 21e (Step S35). At that time, in the cooling mechanism 25 of the pipe 21d, the processing solution is cooled. Therefore, the impurities dissolved in the processing solution are precipitated as solids. After that, by the filter 26 in the pipe 21e, the impurities in the processing solution are filtered out and only the processing solution is collected into the reserve temperature-controlled tank 28.

The reserve temperature-controlled tank 28 uses the heater 28a to heat the collected processing solution to a predetermined temperature again (Step S36). When the processing solution is heated up to the predetermined temperature, the substrate processing apparatus 1 opens the valve V8 and operates the circulation pump 22. The processing solution in the reserve temperature-controlled tank 28 is thereby supplied to the inside bath 11 through the pipes 21g and 21a (Step S37).

After that, the substrate processing apparatus 1 cleans the filter 26. (Step S38). The operation flow for cleaning the filter 26 is the same as that for cleaning the filter 26 as shown in FIG. 4. Specifically, first, the valve V5 is closed and the valve V11 is opened, and the path toward the drainage cooling tank 30 (drainage path) is set to serve as the passage for the solution (Step S21). Then, the valve V9 is opened and the filter cleaning solution is supplied from the filter cleaning solution supplier 29 to the filter 26 through the pipes 21h, 21i and 21e (Step S22). The impurities accumulated in the filter 26 are dissolved again by the filter cleaning solution and can pass the filter 26. Then, the filter cleaning solution containing the ingredients of the impurities, after passing through the filter 26, is discharged to the drainage cooling tank 30 through the pipes 21e, 21k and 21m.

After that, the valve V9 is closed and the valve V13 is opened. A new processing solution is thereby supplied from the processing solution supplier 31 to the pipe 21e through the pipes 21n and 21o (Step S23). The processing solution supplied to the pipe 21e cleans off the filter cleaning solution adhered on the pipe 21e and the filter 26 and is discharged to the drainage cooling tank 30 through the pipes 21k and 21m. In the drainage cooling tank 30, the processing solution and the filter cleaning solution are cooled by the cooling mechanism 30a (Step S24). Then, after the processing solution and the filter cleaning solution are cooled up to the temperature where the solutions can be discharged, the valve V18 is opened and the processing solution and the filter cleaning solution are discharged to the drainage line (Step S25). Thus, the processing for the substrates W in the substrate processing apparatus 1 is completed.

As discussed above, the substrate processing apparatus 1 precipitates the impurities by cooling the processing solution and removes the precipitated impurities by using the filter 26. It therefore becomes possible to maintain the performance of the processing solution and reuse the processing solution. Further, the frequency of changing the processing solution to a new solution decreases, and this causes an increase in availability of the substrate processing apparatus 1 and a decrease in consumption and drainage of the processing solution. Though the circulation path via the filter 26 (the first circulation path) is used in the above exemplary case, the circulation path via the filter 27 (the second circulation path) may be used, or the first and second circulation paths may be used at the same time.

Especially, the substrate processing apparatus 1 collects the processing solution from the outside bath 12 and the bottom of the inside bath 11. It is therefore possible to quickly collect the processing solution and remove the impurities in the processing solution. This further increases the availability of the substrate processing apparatus 1.

Further, the substrate processing apparatus 1 comprises the reserve temperature-controlled tank 28 for heating the processing solution on the downstream side of the filters 26 and 27 in the circulation paths for the processing solution. The substrate processing apparatus 1 can therefore remove the impurities in the processing solution while keeping the temperature of the processing solution in the processing bath 10.

The substrate processing apparatus 1 further has drainage paths which branch out from the first and second circulation paths, respectively. By controlling opening and closing of the valves V5, V7, V11 and V12, switching between the main path and the drainage path in each circulation path can be performed. Therefore, for cleaning the filters 26 and 27, the passage for the solution can be switched to the drainage path and it is thereby possible to prevent the filter cleaning solution to be supplied to the processing bath 10.

Further, after supplying the filter cleaning solution to the filters 26 and 27, the substrate processing apparatus 1 supplies the processing solution to the pipes 21e and 21f and the filters 26 and 27. It is therefore possible to prevent the filter cleaning solution to be adhered to the pipes 21e and 21f or the filters 26 and 27 and left thereon.

<1-4. Variations>

Though discussion has been made above on the case where the processing solution is reused, there may be a case where part of the processing solution is discharged in mid-course of circulation and a new processing solution is supplementally added. Specifically, after collecting the processing solution into the reserve temperature-controlled tank 28, the valve V17 is opened. With this operation, a predetermined amount of processing solution is discharged from the reserve temperature-controlled tank 28 through the pipe 21s to the drainage cooling tank 30a. Then, the valve V15 is opened and the processing solution is supplementally added from the processing solution supplier 31 through the pipe 21q to the reserve temperature-controlled tank 28. It is thereby possible to prevent degradation of the processing solution due to some cause other than impurities and maintain performance of the processing solution.

There may be another case where all the processing solution in the processing bath 10 is changed once in a predetermined number of processings. Specifically, after a predetermined number of processings for the substrates W are completed, the valve V16 is opened. The processing solution is thereby collected from the processing bath 10 through the pipe 21r to the drainage cooling tank 30. In the drainage cooling tank 30, the processing solution is cooled by the cooling mechanism 30a. Then, after the processing solution is cooled up to the temperature where the solutions can be discharged, the valve V18 is opened and the processing solution is discharged to the drainage line. After that, the valves V8 and V15 are opened and the circulation pump 22 is operated, to supply a new processing solution to the processing bath 10. It is thereby possible to prevent degradation of the processing solution due to some cause other than impurities and maintain performance of the processing solution.

Though the filters 26 and 27 are used to remove the impurities in the above exemplary case, impurity removing means other than the filter 26 or 27 may be used. An apparatus, for example, which separates impurities from the processing solution by centrifugal separation and removes the impurities, may be used.

Though discussion has been made above on the case where the processing solution containing phosphoric acid is used and the substrates W are etched therewith, the substrate processing apparatus of the present invention is not limited to an apparatus for such an operation. An apparatus, for example, which uses a processing solution containing hydrogen peroxide water or aqueous ammonia and cleans the substrates W therewith, may be used. Further, an apparatus using a solution whose main ingredient is an organic solvent such as IPA (isopropyl alcohol), HFE (hydrofluoroether) or HFC (hydrofluorocarbon) may be used.

### 2. The Second Preferred Embodiment

<2-1. Constitution of Substrate Processing Apparatus>

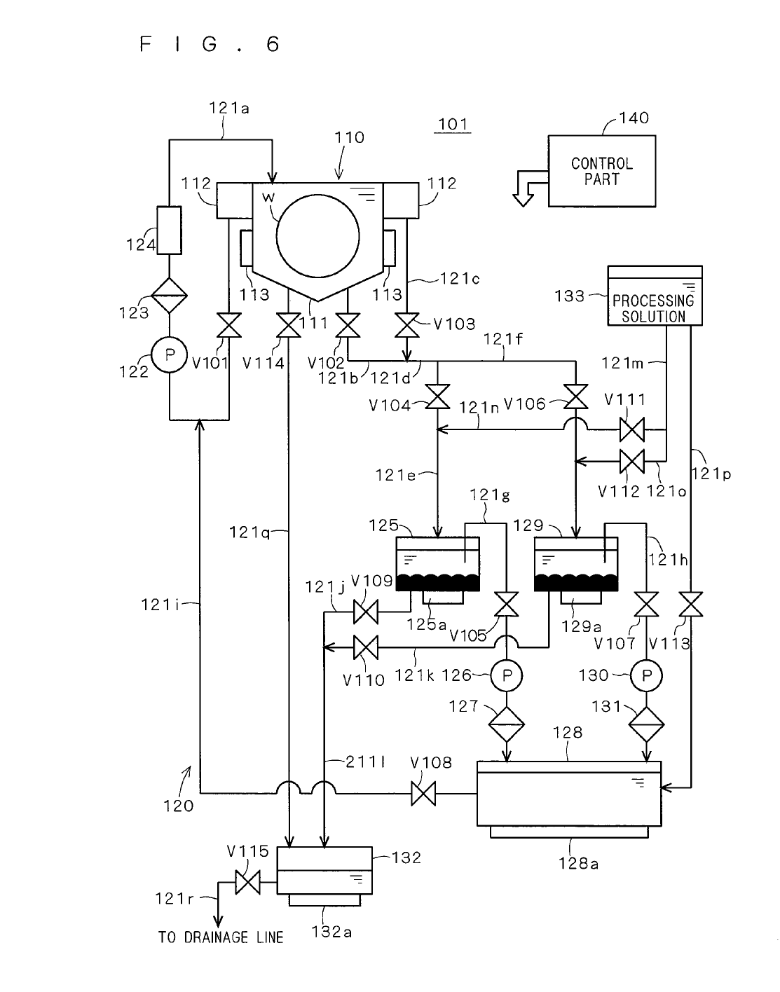

FIG. 6 is a view showing a constitution of a substrate processing apparatus 101 in accordance with the second preferred embodiment of the present invention. This substrate processing apparatus 101 is an apparatus for processing a plurality of substrates W, by immersing the substrates W in a processing solution pooled in a processing bath 110. The substrate processing apparatus 101 mainly comprises the processing bath 110, a piping part 120 and a control part 140. In the second preferred embodiment, discussion will be made on a case where a phosphoric acid (H₃PO₄) solution is used as the processing solution and etching is performed on a surface of each substrate W.

The processing bath 110 is a container for pooling the processing solution therein. The processing bath 110 comprises an inside bath 111 for immersing the substrates W therein and outside baths 12 provided on the upper ends of the outside surface of the inside bath 111. The processing solution supplied to the inside bath 111 is pooled in the inside bath 111 and then overflows into the outside bath 112 from an opening at the upper portion of the inside bath 111. On both sides of the inside bath 111, heaters 113 are provided. When the heaters 113 are operated, the processing solution pooled inside the inside bath 111 is heated and kept at a predetermined temperature (e.g., 160° C.).

At the upper portion of the processing bath 110 provided is a not-shown lifter for holding the substrates W. The substrates W are held by the lifter and conveyed vertically, moving between a drawing-up position at an upside of the processing bath 110 and an immersing position inside the inside bath 111 (the position shown in FIG. 6). When the processing solution is pooled in the inside bath 111 and the substrates W are lowered, the substrates W are immersed into the processing solution and the surfaces of the substrates W are etched.

The piping part 120 consists of a plurality of pipes 121a to 121r. The pipe 121a has an upstream end which is connected to the outside bath 112 and a downstream end which is connected to the inside bath 111. In the path of the pipe 121a, a valve V101, a circulation pump 122, a filter 123 and a heater 124 are provided in this order from the upstream side. Therefore, when the valve V101 is opened and the circulation pump 122 is operated, the processing solution which overflows into the outside bath 112 from the inside bath 111 flows into the pipe 121a, circulating therein toward the inside bath 111. On the way in the path of the pipe 121a to the inside bath 111, impurities in the processing solution are removed by the filter 123. When the heater 124 is operated, the circulating processing solution is heated and kept at a predetermined temperature.

The pipe 121b has an upstream end which is connected to the bottom of the inside bath 111 and at some midpoint in the path of the pipe 121b, a valve V102 is connected thereto. Therefore, when the valve V102 is opened, the processing solution pooled in the inside bath 111 quickly flows out into the pipe 121b. The pipe 121c has an upstream end which is connected to the outside bath 112 and at some midpoint in the path of the pipe 121c, a valve V103 is inserted. Therefore, when the valve V103 is opened, the processing solution which overflows into the outside bath 112 flows out into the pipe 121c. The downstream end of the pipe 121b and the downstream end of the pipe 121c are joined into one pipe 121d.

The downstream end of the pipe 121d branches out into two pipes 121e and 121f. At some midpoint in the path of the pipe 121e, a valve V104 is inserted and the downstream end of the pipe 121e is connected to a cooling tank 125. The processing solution flowing inside the pipe 121e flows into the cooling tank 125 and temporarily pooled in the cooling tank 125. A cooling mechanism 125a is provided on the bottom side of the cooling tank 125. Therefore, when the cooling mechanism 125a is operated, the processing solution pooled in the cooling tank 125 is cooled.

Further, the pipe 121g is connected into the cooling tank 125. In the path of the pipe 121g, a valve V105, a lift pump 126 and a filter 127 are provided in this order from the upstream side. The downstream end of the pipe 121g is connected to a reserve temperature-controlled tank 128. Therefore, when the valve V105 is opened and the lift pump 126 is operated, the supernatant fluid of the processing solution pooled in the cooling tank 125 is drawn up to the pipe 121g, going through the filter 127, and supplied to the reserve temperature-controlled tank 128.

On the other hand, at some midpoint in the path of the pipe 121f, a valve V106 is inserted and the downstream end of the pipe 121f is connected to a cooling tank 129. The processing solution flowing in the pipe 121f flows into the cooling tank 129 and temporarily pooled in the cooling tank 129. A cooling mechanism 129a is provided on the bottom side of the cooling tank 129. Therefore, when the cooling mechanism 129a is operated, the processing solution pooled in the cooling tank 129 is cooled.

Further, the pipe 121h is connected into the cooling tank 129. In the path of the pipe 121h, a valve V107, a lift pump 130 and a filter 131 are provided in this order from the upstream side. The downstream end of the pipe 121h is connected to the reserve temperature-controlled tank 128. Therefore, when the valve V107 is opened and the lift pump 130 is operated, the supernatant fluid of the processing solution pooled in the cooling tank 129 is drawn up to the pipe 121h, going through the filter 131, and supplied to the reserve temperature-controlled tank 128.

A heater 128a is provided on the bottom side of the reserve temperature-controlled tank 128. Therefore, when the heater 128a is operated, the processing solution pooled in the reserve temperature-controlled tank 128 is heated up to a predetermined temperature.

The pipe 121i has an upstream end which is connected to the reserve temperature-controlled tank 128 and a downstream end which is connected to the upstream side of the circulation pump 122 in the pipe 121a. At some midpoint in the path of the pipe 121g, a valve V108 is inserted. Therefore, when the valve V108 is opened and the circulation pump 122 is operated, the processing solution pooled in the reserve temperature-controlled tank 128 flows into the pipe 121a through the pipe 121i and supplied to the inside bath 111 via the filter 123 and the heater 124.

The pipe 121j is connected to the bottom of the cooling tank 125. Similarly, the pipe 121k is connected to the bottom of the cooling tank 129. At some midpoints in the paths of the pipes 121j and 121k, valves V109 and V110 are inserted, respectively, and the downstream end of the pipe 121j and the downstream end of the pipe 121k are joined into one pipe 121l. The downstream end of the pipe 121l is connected to a drainage tank 132. Therefore, when the valve V109 is opened, the processing solution is discharged from the bottom of the cooling tank 125 to the drainage tank 132 through the pipes 121j and 121l. Further, when the valve V110 is opened, the processing solution is discharged from the bottom of the cooling tank 129 to the drainage tank 132 through the pipes 121k and 121l.

The processing solution supplier 133 is a fluid supply for supplying a new (unused) processing solution. To the processing solution supplier 133, the pipe 121m is connected. The downstream end of the pipe 121m branches out into the pipes 121n and 121o. At some midpoint in the path of the pipe 121n, a valve V111 is inserted, and the downstream end of the pipe 121n is connected to the pipe 121e. Therefore, when the valve V111 is opened, the processing solution is supplied from the processing solution supplier 133 to the cooling tank 125 through the pipes 121m, 121n and 121e. Similarly, at some midpoint in the path of the pipe 121o, a valve V112 is inserted, and the downstream end of the pipe 121o is connected to the pipe 121f. Therefore, when the valve V112 is opened, the processing solution is supplied from the processing solution supplier 133 to the cooling tank 129 through the pipes 121m, 121o and 121f.

To the processing solution supplier 133, the pipe 121p is also connected. At some midpoint in the path of the pipe 121p, a valve V113 is inserted, and the downstream end of the pipe 121p is connected to the reserve temperature-controlled tank 128. Therefore, when the valve V113 is opened, a new processing solution is supplied from the processing solution supplier 133 to the reserve temperature-controlled tank 128.

The pipe 121q has an upstream end which is connected to the bottom of the inside bath 111 and a downstream end which is connected to the drainage tank 132. At some midpoint in the path of the pipe 121q, a valve V114 is inserted. Therefore, when the valve V114 is opened, the processing solution pooled in the inside bath 111 is quickly discharged into the drainage tank 132 through the pipe 121q.

A cooling mechanism 132a is provided on the drainage tank 132. When the cooling mechanism 132a is operated, the processing solution pooled in the drainage tank 132 is cooled up to a temperature where it can be disposed of. Further, to the drainage tank 132, the pipe 121r is connected. At some midpoint in the path of the pipe 121r, a valve V115 is inserted and the downstream end of the pipe 121r is connected to a drainage line. Therefore, when the valve V115 is opened, the processing solution cooled in the drainage tank 132 is discharged into the drainage line.

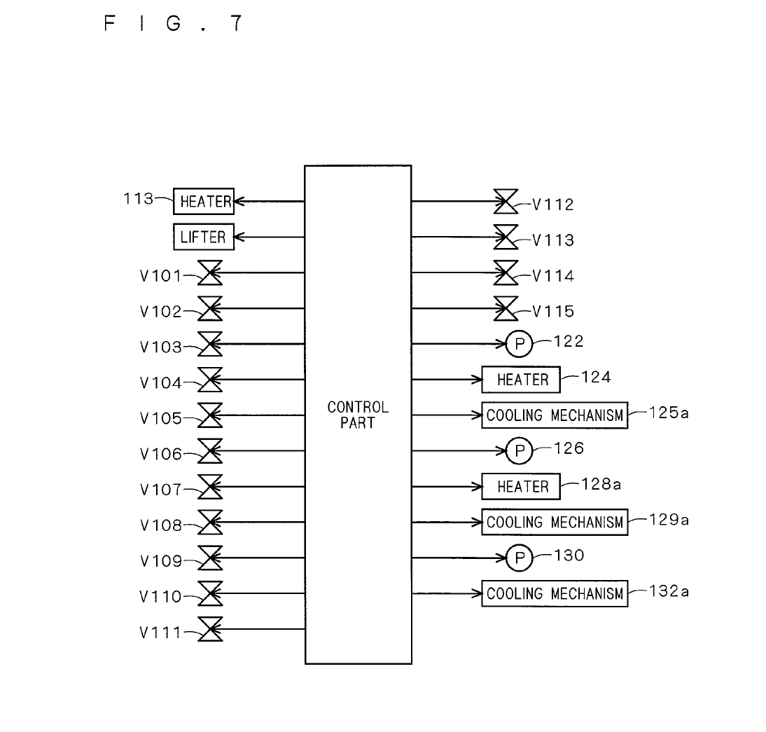

The control part 140 is an information processing part for controlling operations of constituent elements in the substrate processing apparatus 101. The control part 140 is formed of a computer consisting of a CPU and memories. FIG. 7 is a block diagram showing an electric connection between the control part 140 and the constituent elements. As shown in FIG. 7, the control part 140 is electrically connected to the heaters 113, the lifter, the valves V101 to V115, the circulation pump 122, the heater 124, the cooling mechanism 125a, the lift pump 126, the heater 128a, the cooling mechanism 129a, the lift pump 130 and the cooling mechanism 132a, and controls the operations of those constituents.

<2-2. Operation of Substrate Processing Apparatus (For Continuously Removing Impurities>

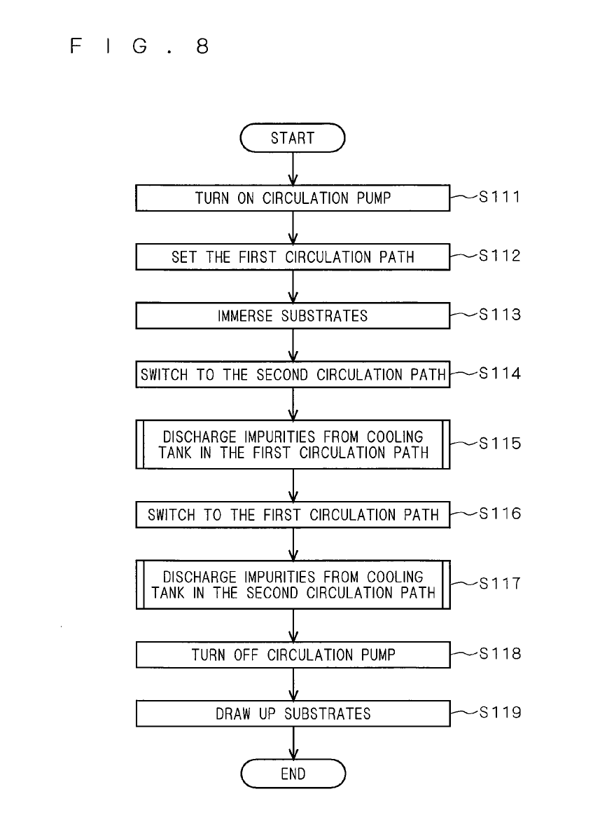

Next, discussion will be made on an operation of the substrate processing apparatus 101 having the above constitution. The discussion will start with a case where the substrates W are processed in the processing bath 110 while impurities in the processing solution are continuously removed, with reference to the flowchart of FIG. 8. To perform the operation of the substrate processing apparatus 101 discussed below, the control part 140 controls the operations of the heaters 113, the lifter, the valves V101 to V115, the circulation pump 122, the heater 124, the cooling mechanism 125a, the lift pump 126, the heater 128a, the cooling mechanism 129a, the lift pump 130, the cooling mechanism 132a and the like.

First, in the substrate processing apparatus 101, the valves V108 and V113 are opened and the circulation pump 122 is operated. The processing solution is thereby supplied from the processing solution supplier 133 to the inside bath 111 through the pipe 121p, the reserve temperature-controlled tank 128, the pipes 121i and 121a and pooled in the inside bath 111 (Step S111). When pooled up to the uppermost position of the inside bath 111, the processing solution overflows from the upper portion of the inside bath 111 into the outside bath 112.

When the processing solution is pooled in the inside bath 111, the heater 128a of the reserve temperature-controlled tank 128, the heater 124 in the pipe 121a and the heaters 113 of the inside bath 111 are operated. The processing solution pooled in the inside bath 111 is thereby heated and kept at a predetermined temperature (e.g., 160° C.) which is suitable for the etching operation.

Next, the valves V101, V102, V106, V107 and V109 to V115 are closed and the valves V103 to V105 and V108 are opened. Then, the circulation pump 122 and the lift pump 126 are operated. A circulation path via the cooling tank 125 (hereinafter, referred to as “the first circulation path”) is thereby set to serve as the passage for the processing solution (Step S112). In the first circulation path, the processing solution which overflows from the inside bath 111 into the outside bath 112 circulates through the pipes 121c, 121d and 121e, the cooling tank 125, the pipe 121g, the reserve temperature-controlled tank 128 and the pipes 121i and 121a to the inside bath 111.

Subsequently, by lowering the lifter which holds the substrates W, the substrates W are immersed into the processing solution pooled in the inside bath 111 (Step S113). The oxide film or nitride film formed on the substrates W is thereby etched. The ingredients (SiO₂, SiN₃ or the like) of the oxide or nitride eluted from the surfaces of the substrates W by etching are mixed into the processing solution as impurities.

The processing solution containing the impurities overflows from the upper portion of the inside bath 111 into the outside bath 112 and begins to flow into the first circulation path from the outside bath 112. Then, in the first circulation path, the processing solution is temporarily pooled in the cooling tank 125 and cooled by the cooling mechanism 125a. Since the saturated dissolution concentration of the impurities to the processing solution decreases as the temperature of the processing solution falls, when the processing solution is cooled, the impurities dissolved in the processing solution are precipitated as solids and settled on the bottom of the cooling tank 125.

On the other hand, the supernatant fluid of the processing solution pooled in the cooling tank 125 is drawn up to the pipe 121g, going through the filter 127, and pooled in the reserve temperature-controlled tank 128. The reserve temperature-controlled tank 128 heats the pooled processing solution up to a predetermined temperature again by the heater 128a. Then, the processing solution heated by the reserve temperature-controlled tank 128 is supplied to the inside bath 111 through the pipes 121i and 121a and reused to process the substrates W. The processing solution is also heated by the heater 124 in the pipe 121a and the heaters 113 in the inside bath 111. It is thereby possible to prevent a decrease in temperature of the processing solution in the pipes 121i and 121a and keep the processing solution at the predetermined temperature.

After the substrates W have been immersed for a predetermined time, next, the valves V104 and V105 are closed and the lift pump 126 is stopped. Then, the valves V106 and V107 are opened and the lift pump 130 is operated. The passage for the processing solution is switched to the circulation path via the cooling tank 129 (hereinafter, referred to as “the second circulation path”) (Step S114). In the second circulation path, the processing solution which overflows into the outside bath 112 circulates through the pipes 121c, 121d and 121f, the cooling tank 129 and the pipes 121i and 121a to the inside bath 111.

The processing solution flowing out from the outside bath 112 to the second circulation path is, first, temporarily pooled in the cooling tank 129 and cooled by the cooling mechanism 129a. In the cooled processing solution, the impurities are precipitated as solids and settled on the bottom of the cooling tank 129. On the other hand, the supernatant fluid of the processing solution pooled in the cooling tank 129 is drawn up to the pipe 121h, going through the filter 131, and pooled in the reserve temperature-controlled tank 128. The processing solution pooled in the reserve temperature-controlled tank 128 is heated by the heater 128a and supplied to the inside bath 111 through the pipes 121i and 121a. Thus, in the second circulation path, the same circulation of the processing solution is performed as that in the first circulation path.

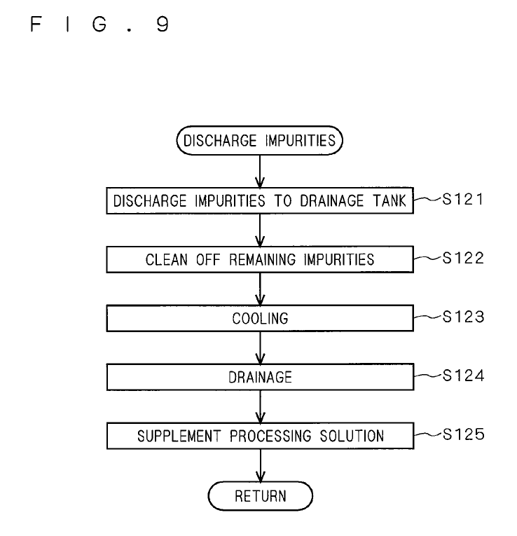

While the second circulation path is used, the impurities settled in the cooling tank 125 are discharged in the first circulation path (Step S115). FIG. 9 is a flowchart showing a detailed operation flow for discharging the impurities. To discharge the impurities from the cooling tank 125, first, the valve V109 is opened. The impurities settled on the bottom of the cooling tank 125 are thereby discharged, together with a small amount of processing solution remaining in the cooling tank 125, to the drainage tank 132 through the pipes 121j and 121l (Step S121).

Next, the valve V111 is opened and the processing solution is supplied from the processing solution supplier 133 to the cooling tank 125 through the pipes 121m, 121n and 121e. The impurities remaining on the bottom of the cooling tank 125 is thereby cleaned off and discharged through the pipes 121j and 121l to the drainage tank 132 (Step S122). When discharge of the impurities is completed, the valves V111 and V109 are closed. In the drainage tank 132, the processing solution is further cooled by the cooling mechanism 132a (Step S123). Then, after the processing solution is cooled up to a temperature where the solution can be discharged, the valve V115 is opened and the processing solution is discharged to the drainage line (Step S124).

Further, after discharge of the impurities from the cooling tank 125 is completed, the valve V113 is opened for a predetermined time. The processing solution as much as that discharged together with the impurities is thereby supplementally added to the reserve temperature-controlled tank 128 (Step S125).

Referring back to FIG. 8, after a predetermined time from the time when the passage is switched to the second circulation path, next, the valves V106 and V107 are closed and the lift pump 130 is stopped. Then, the valves V104 and V105 are opened and the lift pump 126 is operated. The passage for the processing solution is thereby switched to the first circulation path again (Step S116). In the first circulation path, like in the above-discussed Step S113, first, the processing solution flowing out from the outside bath 112 is temporarily pooled in the cooling tank 125 and cooled by the cooling mechanism 125a. In the cooled processing solution, the impurities are precipitated as solids and settled on the bottom of the cooling tank 125. On the other hand, the supernatant fluid of the processing solution pooled in the cooling tank 125 is drawn up to the pipe 121g, going through the filter 127, and pooled in the reserve temperature-controlled tank 128. The processing solution pooled in the reserve temperature-controlled tank 128 is heated by the heater 128a and supplied to the inside bath 111 through the pipes 121i and 121a.

While the first circulation path is used, the impurities settled in the cooling tank 129 are discharged in the second circulation path (Step S117). The operation flow for discharging the impurities is the same as that for discharging the impurities as shown in FIG. 9. Specifically, first, the valve V110 is opened. The impurities settled on the bottom of the cooling tank 129 are thereby discharged, together with a small amount of processing solution remaining in the cooling tank 129, to the drainage tank 132 through the pipes 121k and 121l (Step S121).

Next, the valve V112 is opened and the processing solution is supplied from the processing solution supplier 133 to the cooling tank 129 through the pipes 121m, 121o and 121 f. The impurities remaining on the bottom of the cooling tank 129 is thereby cleaned off and discharged through the pipes 121k and 121l to the drainage tank 132 (Step S122). When discharge of the impurities is completed, the valves V112 and V110 are closed. In the drainage tank 132, the processing solution is further cooled by the cooling mechanism 132a (Step S123). Then, after the processing solution is cooled up to a temperature where the solution can be discharged, the valve V115 is opened and the processing solution is discharged to the drainage line (Step S124).

Further, after discharge of the impurities from the cooling tank 129 is completed, the valve V113 is opened for a predetermined time. The processing solution as much as that discharged together with the impurities is thereby supplementally added to the reserve temperature-controlled tank 128 (Step S125).

Referring back to FIG. 8, when the processing for the substrates W which takes a predetermined time is completed, the circulation pump 122 and the lift pump 126 are stopped (Step S118). The circulation of the processing solution is thereby stopped. Then, by raising the lifter, the substrates W are drawn up from the inside bath 111 (Step S119). Thus, the processing for the substrates W in the substrate processing apparatus 101 is completed.

As discussed above, the substrate processing apparatus 101 once pools the processing solution in the cooling tank 125 or 129, to cool the processing solution. The substrate processing apparatus 101 thereby precipitates the impurities dissolved in the processing solution, to be settled on the bottom of the cooling tank 125 or 129. Then, the substrate processing apparatus 101 supplies the supernatant fluid of the processing solution pooled in the cooling tank 125 or 129 to the processing bath 110 again. It therefore becomes possible to maintain the performance of the processing solution and reuse the processing solution. Further, the frequency of changing the processing solution to a new solution decreases, and this causes an increase in availability of the substrate processing apparatus 101 and a decrease in consumption and drainage of the processing solution.

Especially, the substrate processing apparatus 101 processes the substrates W while circulating the processing solution, and cools the processing solution and removes the impurities in the circulation path. For this reason, the substrate processing apparatus 101 can remove the impurities in the processing solution without stopping the processing for the substrates W in the processing bath 110. This further increases the availability of the substrate processing apparatus 101.

Further, the substrate processing apparatus 101 comprises the reserve temperature-controlled tank 128 for heating the processing solution on the downstream side of the cooling tanks 125 and 129 in the circulation path of the processing solution. The substrate processing apparatus 101 can therefore remove the impurities in the processing solution while keeping the temperature of the processing solution in the processing bath 110.

The substrate processing apparatus 101 further comprises the filters 127 and 131 for filtering out the impurities on the downstream side of the cooling tanks 125 and 129 in the circulation paths of the processing solution, respectively. For this reason, if a very small amount of impurities are drawn up from the cooling tank 125 or 129 to the pipe 121g or the 121h, the impurities can be filtered out and removed.

The substrate processing apparatus 101 further has the first and second circulation paths which are provided in parallel and comprise the same cooling tanks. By controlling opening and closing of the valves V104 to V107, switching between the first and second circulation paths can be performed. Therefore, if impurities are accumulated in one of the cooling tanks, the other cooling tank can be used by switching of the circulation paths. This further increases the availability of the substrate processing apparatus 101.

Furthermore, the substrate processing apparatus 101 can use one circulation path while discharging the impurities from the cooling tank in the other circulation path. It is therefore possible to discharge the impurities settled on the bottom of the cooling tank 125 or 129 while continuously switching the circulation paths to be used. This further increases the availability of the substrate processing apparatus 101. The number of switching of the circulation paths is not limited to the above exemplary case but may be set as appropriate in accordance with the time period for the processing of the substrates W.

The substrate processing apparatus 101 can supply the processing solution from the processing solution supplier 133 to the cooling tanks 125 and 129. For this reason, when the impurities are discharged from the cooling tank 125 or 129, the impurities remaining on the bottom of the cooling tank 125 or 129 can be cleaned off.

<2-3. Operation of Substrate Processing Apparatus (For Removing Impurities at a Time>

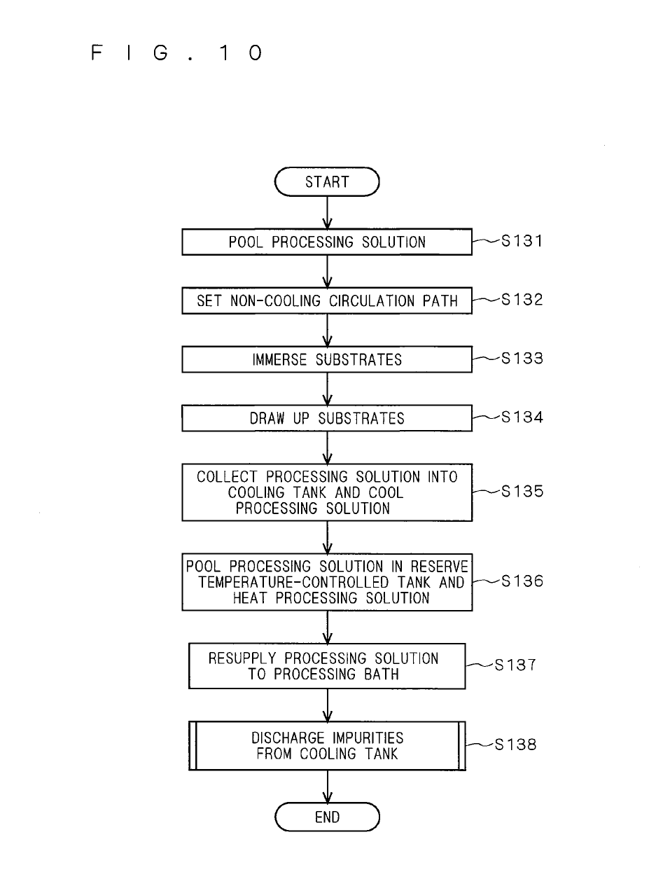

Next, discussion will be made on a case where after processing the substrates W, the above-discussed substrate processing apparatus 101 removes impurities in the processing solution at a time, with reference to the flowchart of FIG. 10. Also to perform the operation of the substrate processing apparatus 101 discussed below, the control part 140 controls the operations of the heaters 113, the lifter, the valves V101 to V115, the circulation pump 122, the heater 124, the cooling mechanism 125a, the lift pump 126, the heater 128a, the cooling mechanism 129a, the lift pump 130, the cooling mechanism 132a and the like.

First, in the substrate processing apparatus 101, the valves V108 and V113 are opened and the circulation pump 122 is operated. The processing solution is thereby supplied from the processing solution supplier 133 to the inside bath 111 through the pipe 121p, the reserve temperature-controlled tank 128, the pipes 121i and 121a and pooled in the inside bath 111 (Step S131). When pooled up to the uppermost position of the inside bath 111, the processing solution overflows from the upper portion of the inside bath 111 into the outside bath 112.

When the processing solution is pooled in the inside bath 111, the heater 128a of the reserve temperature-controlled tank 128, the heater 124 in the pipe 121a and the heaters 113 of the inside bath 111 are operated. The processing solution pooled in the inside bath 111 is thereby heated and kept at a predetermined temperature (e.g., 160° C.) which is suitable for the etching operation.

Next, the valves V102 to V115 are closed and the valve V101 is opened. A circulation path consisting only of the pipe 121a (hereinafter, referred to as “a non-cooling circulation path”) is thereby set to serve as the passage for the processing solution (Step S132). In the non-cooling circulation path, the processing solution which overflows from the inside bath 111 into the outside bath 112 circulates through the filter 123 and the heater 124 to the inside bath 111.

Subsequently, by lowering the lifter which holds the substrates W, the substrates W are immersed into the processing solution pooled in the inside bath 111 (Step S133). The oxide film or nitride film formed on the surfaces of the substrates W is thereby etched. The ingredients (SiO₂, SiN₃ or the like) of the oxide film or nitride film eluted from the surfaces of the substrates W by etching are mixed into the processing solution as impurities. Then, when the processing for the substrates W which takes a predetermined time is completed, the substrates W are drawn up from the inside bath 111 by raising the lifter (Step S134).

After drawing up the substrates W, the substrate processing apparatus 101 closes the valve V101 and opens the valves V102, V103 and V104. The substrate processing apparatus 101 thereby collects the processing solution which is pooled in the inside bath 111 and the outside bath 112, in the cooling tank 125 through the pipes 121b, 121c, 121d and 121e. The processing solution collected to the cooling tank 125 is cooled by the cooling mechanism 125a (Step S135). Therefore, the impurities dissolved in the processing solution are precipitated as solids and settled on the bottom of the cooling tank 125.

Next, the substrate processing apparatus 101 closes the valves V102, V103 and V104 and opens the valve V105. Further, the substrate processing apparatus 101 operates the lift pump 126. The supernatant fluid of the processing solution pooled in the cooling tank 125 is thereby drawn up to the pipe 121g, going through the filter 127, and pooled in the reserve temperature-controlled tank 128. The processing solution pooled in the reserve temperature-controlled tank 128 is heated by the heater 128a up to a predetermined temperature again (Step S136).

When the processing solution is heated up to the predetermined temperature, the substrate processing apparatus 101 closes the valve V105 and stops the lift pump 126. Then, the substrate processing apparatus 101 opens the valve V108 and operates the circulation pump 122. The processing solution in the reserve temperature-controlled tank 128 is thereby supplied to the inside bath 111 through the pipes 121i and 121a, to be reused to process the substrates W (Step S137). Further, the processing solution is also heated by the heater 124 in the pipe 121a and the heaters 113 in the inside bath 111. It is thereby possible to prevent a decrease in temperature of the processing solution in the pipes 121i and 121a and keep the processing solution at the predetermined temperature.

After that, the substrate processing apparatus 101 discharges the impurities settled in the cooling tank 125 (Step S138). The operation flow for discharging the impurities is the same as that for discharging the impurities as shown in FIG. 9. Specifically, first, the valve V109 is opened. The impurities settled on the bottom of the cooling tank 125 are thereby discharged, together with a small amount of processing solution remaining in the cooling tank 125, to the drainage tank 132 through the pipes 121j and 121l (Step S121).

Next, the valve V111 is opened and the processing solution is supplied from the processing solution supplier 133 to the cooling tank 125 through the pipes 121m, 121n and 121e. The impurities remaining on the bottom of the cooling tank 125 is thereby cleaned off and discharged through the pipes 121j and 121l to the drainage tank 132 (Step S122). When discharge of the impurities is completed, the valves V111 and V109 are closed. In the drainage tank 132, the processing solution is further cooled by the cooling mechanism 132a (Step S123). Then, after the processing solution is cooled up to a temperature where the solution can be discharged, the valve V115 is opened and the processing solution is discharged to the drainage line (Step S124).

Further, after discharge of the impurities from the cooling tank 125 is completed, the valve V113 is opened for a predetermined time. The processing solution as much as that discharged together with the impurities is thereby supplementally added to the inside bath 111 from the processing solution supplier 133 through the pipe 121p, the reserve temperature-controlled tank 128, the pipes 121i and 121a (Step S125). Thus, the processing for the substrates W in the substrate processing apparatus 101 is completed.

As discussed above, the substrate processing apparatus 101 once pools the processing solution in the cooling tank 125, to cool the processing solution. The substrate processing apparatus 101 thereby precipitates the impurities dissolved in the processing solution, to be settled on the bottom of the cooling tank 125. Then, the substrate processing apparatus 101 supplies the supernatant fluid of the processing solution pooled in the cooling tank 125 to the processing bath 110 again. It therefore becomes possible to maintain the performance of the processing solution and reuse the processing solution. Further, the frequency of changing the processing solution to a new solution decreases, and this causes an increase in availability of the substrate processing apparatus 101 and a decrease in consumption and drainage of the processing solution. Though the circulation path via the cooling tank 125 (the first circulation path) is used in the above exemplary case, the circulation path via the cooling tank 129 (the second circulation path) may be used, or the first and second circulation paths may be used at the same time.

Especially, the substrate processing apparatus 101 collects the processing solution from the outside bath 112 and the bottom of the inside bath 111. It is therefore possible to quickly collect the processing solution and remove the impurities in the processing solution. This further increases the availability of the substrate processing apparatus 101.

Further, the substrate processing apparatus 101 comprises the reserve temperature-controlled tank 128 for heating the processing solution on the downstream side of the cooling tanks 125 and 129 in the circulation paths for the processing solution. The substrate processing apparatus 101 can therefore remove the impurities in the processing solution while keeping the temperature of the processing solution in the processing bath 110.

The substrate processing apparatus 101 further comprises the filters 127 and 131 for filtering out the impurities on the downstream side of the cooling tanks 125 and 129 in the circulation paths of the processing solution, respectively. For this reason, if a very small amount of impurities are drawn up from the cooling tank 125 or 129 to the pipe 121g or 121h, the impurities can be filtered out and removed.

The substrate processing apparatus 101 can supply the processing solution from the processing solution supplier 133 to the cooling tanks 125 and 129. For this reason, when the impurities are discharged from the cooling tank 125 or 129, the impurities remaining on the bottom of the cooling tank 125 or 129 can be cleaned off.

<2-4. Variations>

Though discussion has been made above on the case where the processing solution is reused, there may be a case where part of the processing solution is actively discharged in mid-course of circulation and a new processing solution is supplementally added. Specifically, after collecting the processing solution into the cooling tank 125 or 129, the valves V109 or V110 is opened for a predetermined time. With this operation, a predetermined amount of processing solution is discharged from the cooling tank 125 or 129 through the pipe 121j or 121k and the pipe 121l to the drainage tank 132. Then, the valve V111 or V112 is opened and the processing solution is supplementally added from the processing solution supplier 133 through the pipe 121m and the pipe 121n or 121o to the cooling tank 125 or 129. It is thereby possible to prevent degradation of the processing solution due to some cause other than impurities and maintain performance of the processing solution.

There may be another case where all the processing solution in the processing bath 110 is changed once in a predetermined number of processings. Specifically, after a predetermined number of processings for the substrates W are completed, the valve V114 is opened. The processing solution is thereby collected from the processing bath 110 through the pipe 121q to the drainage tank 132. In the drainage tank 132, the processing solution is cooled by the cooling mechanism 132a. Then, after the processing solution is cooled up to the temperature where the solutions can be discharged, the valve V115 is opened and the processing solution is discharged to the drainage line. After that, the valves V108 and V113 are opened and the circulation pump 122 is operated, to supply a new processing solution to the processing bath 110. It is thereby possible to prevent degradation of the processing solution due to some cause other than impurities and maintain performance of the processing solution.

Though discussion has been made above on the case where the processing solution containing phosphoric acid is used and the substrates W are etched therewith, the substrate processing apparatus of the present invention is not limited to an apparatus for such an operation. An apparatus, for example, which uses a processing solution containing hydrogen peroxide water or aqueous ammonia and cleans the substrates W therewith, may be used. Further, an apparatus using a solution whose main ingredient is an organic solvent such as IPA (isopropyl alcohol), HFE (hydrofluoroether) or HFC (hydrofluorocarbon) may be used.

While the invention has been shown and described in detail, the foregoing description is in all aspects illustrative and not restrictive. It is therefore understood that numerous modifications and variations can be devised without departing from the scope of the invention.

1-20. (canceled)

21. A substrate processing apparatus for processing a substrate with a processing solution, the apparatus comprising:
a processing bath for accommodating a substrate and pooling processing solution therein;
a cooling circulation path for supplying processing solution discharged from said processing bath back to said processing bath;
a cooling part for cooling the processing solution at some midpoint in said cooling circulation path;
one or more impurity removing parts for removing impurities contained in a processing solution on the downstream side of said cooling part at some midpoint in said cooling circulation path;
a non-cooling circulation path for supplying, without said cooling part, the processing solution discharged from said processing bath back to said processing bath; and
a first switching part for switching between said cooling circulation path and said non-cooling circulation path.

22. The substrate processing apparatus according to claim 21, further comprising:
a heating part for heating the processing solution on the downstream side of said one or more impurity removing parts at some midpoint in said cooling circulation path.

23. The substrate processing apparatus according to claim 21, wherein
said processing bath comprises an inside bath for accommodating a substrate and processing the substrate and an outside bath provided at an upper portion outside said inside bath, for receiving the processing solution which overflows from said inside bath, and
said cooling circulation path supplies the processing solution discharged from said outside bath back to said inside bath.

24. The substrate processing apparatus according to claim 21, wherein
said cooling circulation path supplies the processing solution discharged from a bottom of said processing bath back to said processing bath.

25. The substrate processing apparatus according to claim 21, wherein
said circulation path comprises a first circulation path and a second circulation path, and
said one or more impurity removing parts is provided in each of said first circulation path and said second circulation path,
said substrate processing apparatus further comprising;
a second switching part for switching between said first circulation path and said second circulation path.

26. The substrate processing apparatus according to claim 21, wherein
said one or more impurity removing parts comprises a filter for filtering impurities in the processing solution,
said substrate apparatus further comprising
a filter cleaning part for cleaning said filter.

27. The substrate processing apparatus according to claim 26, wherein
said filter cleaning part comprises a filter cleaning solution supply part for supplying filter cleaning solution which dissolves impurities to said filter.

28. The substrate processing apparatus according to claim 27, further comprising:
a drainage path which branches out from said circulation path on the downstream side of said filter at some midpoint in said cooling circulation path; and
a drainage switching part for switching between said cooling circulation path and said drainage path.

29. The substrate processing apparatus according to claim 26, further comprising
a processing solution supply part for supplying the processing solution on the upstream side of said filter at some midpoint in said cooling circulation path.

30. The substrate processing apparatus according to claim 22, further comprising
a processing solution pooling bath for pooling the processing solution therein on the downstream side of said one or more impurity removing parts at some midpoint in said cooling circulation path,
wherein said heating part heats the processing solution pooled in said processing solution pooling bath.
